(19) United States
(12) Patent Application Publication
(10) Pub. No.: US 2004/0102048 A1
(43) Pub. Date: May 27, 2004

(54) Method for manufacturing semiconductor device

(75) Inventor: Atsumi Yamaguchi, Tokyo (JP)

Correspondence Address: LEYDIG VOIT & MAYER, LTD, 700 THIRTEENTH ST. NW, SUITE 300, WASHINGTON, DC, 20005-3960, US

(73) Assignee: Renesas Technology Corp., Tokyo (JP)

(21) Appl. No.: 10/457,588

(22) Filed: Jun. 10, 2003

(30) Foreign Application Priority Data
Nov. 25, 2002 (JP) 2002-341304

(51) Int. Cl. H01L 21/311

(52) U.S. Cl. 438/694

(57) ABSTRACT

According to the present invention, in a method for manufacturing a semiconductor device, an underlayer film is formed on a substrate. A resist pattern is formed on the underlayer film. A spin-on glass film is formed on the underlayer film and the resist pattern so as to cover the resist pattern. The resist pattern is removed to produce a reversal pattern in the spin-on glass film. The underlayer film is etched by using the spin-on glass film as a mask to form a fine pattern.

### BACKGROUND OF THE INVENTION

1. Field of the Invention

The present invention relates to a method for manufacturing a semiconductor device. More particularly, this method is suitable for forming a fine line pattern or space pattern on a substrate.

2. Background Art

A general method for forming a fine pattern on a semiconductor substrate comprises the steps of: forming a silicon oxide film and a polysilicon film on a substrate; coating the surface of the polysilicon film with a resist; exposing the resist by irradiating exposure light to it through a reticle; carrying out a development process to form a resist pattern; etching the polysilicon film, the silicon oxide film, and the substrate using the resist pattern as a mask. Each step may include a heat treatment process as necessary. For example, see Japanese Laid-Open Patent Publication No. 2-271358 (1990), pp. 1-2.

In manufacture of a semiconductor device, it is generally necessary to repeat the process as mentioned above of forming a predetermined pattern on a predetermined layer approximately 20 to 30 times. In recent years, since semiconductor integrated circuits have been highly integrated and designed to exhibit high performance, the patterns required for the semiconductor integrated circuits have become fine.

For example, currently available mass produced DRAMs (Dynamic Random Access Memories) of 64 Mbits or 256 Mbits require a resist pattern designed in a 0.13 to 0.18 μm rule. Their photolithographic process employs KrF excimer laser light (an ultraviolet light) with a wavelength of 248 nm. In addition, further miniaturization of patterns will require enhancing the dimensional accuracy and overlay accuracy. However, the smaller the size of a pattern, the more difficult it is to form the pattern. Especially, with a line size of 100 nm or smaller, the problem of “falling down” of a pattern occurs.

As for random logic devices, devices of a 0.13 μm rule are currently mass-produced, and a device using a 0.10 μm rule is being developed. In the manufacture of a random logic device, it is necessary to form any arbitrary line and space patterns, from discrete patterns to dense patterns, within a single chip. To manufacture such a random logic device, a photolithographic technique using ArF excimer laser light with a wavelength of 193 nm is now being put into general practical use.

As devices become more miniaturized, however, it will become more difficult to meet the requirements of both the line and space patterns at the same time, which is necessary for manufacture of random logic devices. Furthermore, the edge portions of the resist line pattern or space pattern considerably retreat from the corresponding mask design positions, making it difficult to increase the pattern density, that is, the degree of integration of the device. For example, the edge portions of a line pattern having a size of 100 nm retreats approximately 40 nm, while the edge portions of a space pattern having a size of 140 nm retreats approximately 20 nm.

As described above, when a conventional pattern forming method is used to form a pattern having a size of 100 nm or less, the problem of “falling down” of the pattern occurs. Furthermore, a narrower pattern line width means a higher aspect ratio with respect to the resist film thickness. Generally, setting the aspect ratio to 3 or more is likely to lead to “falling down” of the pattern. This phenomenon is caused by the high surface tension of water at the time of desiccation after rinsing in the development process. Especially, the narrower the line intervals of a pattern, the more likely that the pattern will “fall down”.

Further, it is difficult to form a line pattern and a space pattern at the same time if a resolution is set close to its limit (maximum value). For example, suppose that exposure is carried out by an off-axis method using ArF excimer laser light (wavelength) with a “⅔ annular illumination aperture” whose numerical aperture (NA) is 0.70. In such a case, it is difficult to form a line pattern and a space pattern at the same time.

Still further, the edge portions of a resist line pattern or space pattern considerably retreat from the corresponding mask design positions. This phenomenon becomes more noticeable with a narrower line width or space width. Therefore, the phenomenon puts a limit on the miniaturization of patterns.

### SUMMARY OF THE INVENTION

The present invention has been devised to solve the above problems. It is, therefore, an object of the present invention to provide an improved manufacturing method of a semiconductor device, capable of forming fine patterns.

According to one aspect of the present invention, in a method for manufacturing a semiconductor device, an underlayer film is formed on a substrate. A resist pattern is formed on the underlayer film. A spin-on glass film is formed on an exposed surface portion of the underlayer film. The resist pattern is removed. The underlayer film is etched using the spin-on glass film as a mask.

According to another aspect of the present invention, in a method for manufacturing a semiconductor device, an underlayer film is formed on a substrate. A first resist pattern is formed on the underlayer film. A first spin-on glass film is formed on an exposed surface portion of the underlayer film. A surface of the first spin-on glass film is flattened until a surface of the first resist pattern is exposed. A second spin-on glass film is formed on the first spin-on glass film. A second resist pattern is formed on the second spin-on glass film. The second spin-on glass film is etched by using the second resist pattern as a mask. Further, the first resist pattern is etched by using the second spin-on glass film as a mask. The underlayer film is etched by using both the second spin-on glass film and the first spin-on glass film as masks.

Other and further objects, features and advantages of the invention will appear more fully from the following description.

### BRIEF DESCRIPTION OF THE DRAWINGS

FIG. 1 is a flowchart illustrating a manufacturing method of a semiconductor device according to a first embodiment of the present invention;

FIGS. 2(a) to (d) and FIGS. 3(a) to (f) are schematic cross-sectional views of a semiconductor device as it is formed, illustrating the first several processes of the manufacturing method of the first embodiment of the present invention;

FIG. 4 is a flowchart illustrating a manufacturing method of a semiconductor device according to a second embodiment of the present invention;

FIGS. 5(a) to (d) are schematic cross-sectional views of a semiconductor device as it is formed, illustrating the processes for forming a fine pattern according to the second embodiment of the present invention;

FIG. 6 is a flowchart illustrating a manufacturing method of a semiconductor device according to a third embodiment of the present invention;

FIGS. 7(a) to (e) and FIGS. 8(a) to (e) are schematic cross-sectional views of a semiconductor device as it is formed, illustrating the processes for forming a fine pattern according to the third embodiment of the present invention;

FIG. 13 is a flowchart illustrating a manufacturing method of a semiconductor device according to a fifth embodiment of the present invention;

FIGS. 14(a), (b) and (c) to FIGS. 20(a), (b) and (c) are schematic diagrams illustrating the processes for forming a fine pattern according to the fifth embodiment of the present invention;

FIG. 21 is a flowchart illustrating a manufacturing method of a semiconductor device according to a sixth embodiment of the present invention.

FIGS. 22(a), (b) and (c) to FIGS. 28(a), (b) and (c) are schematic diagrams illustrating the processes for manufacturing a semiconductor device according to the sixth embodiment of the present invention.

### DETAILED DESCRIPTION OF THE PREFERRED EMBODIMENTS

Preferred embodiments of the present invention will be described below with reference to the accompanying drawings. It should be noted that the same or corresponding components in the figures are denoted by like numerals to simplify or omit their explanation.

First Embodiment

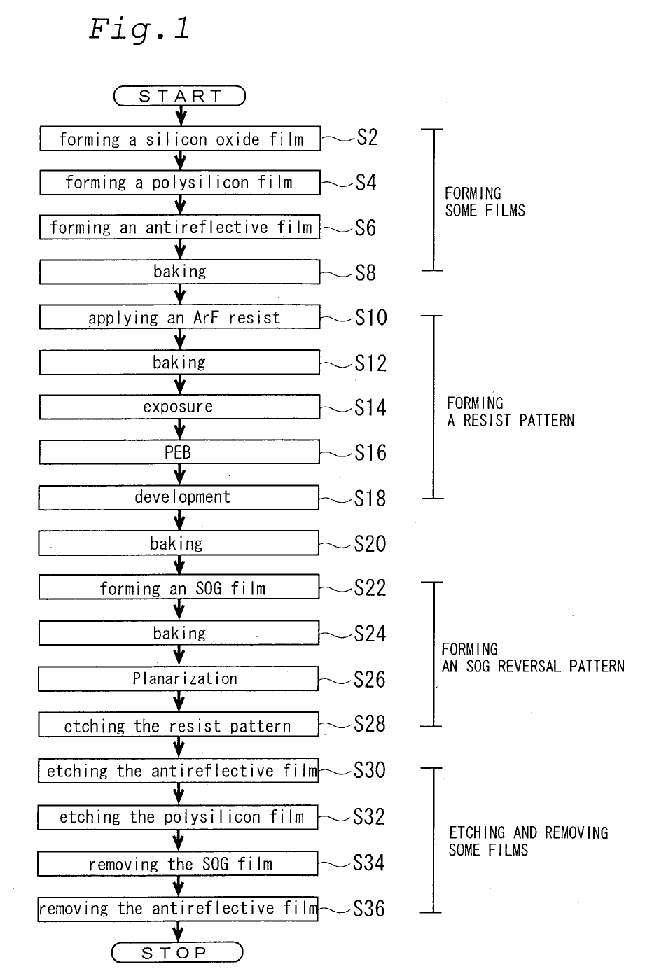

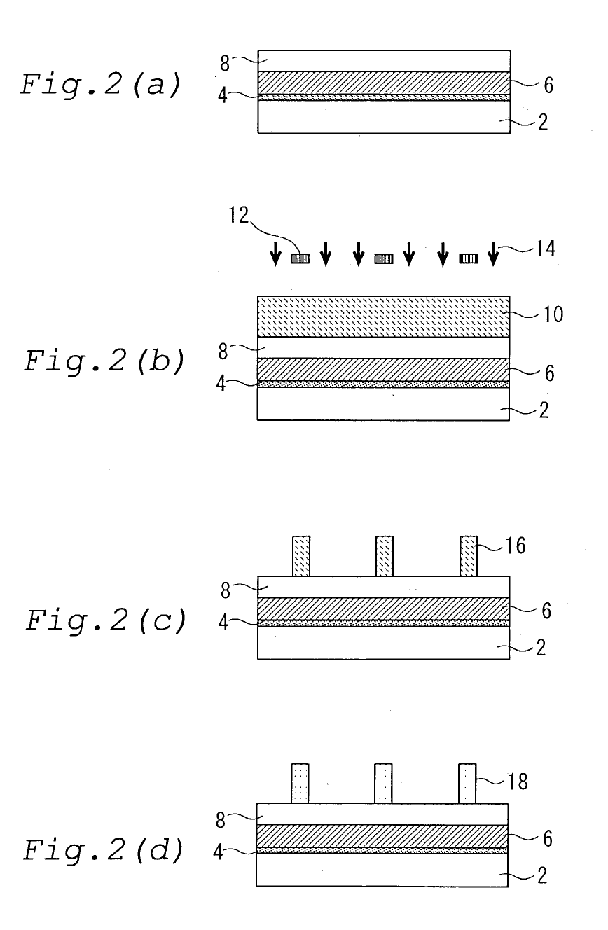

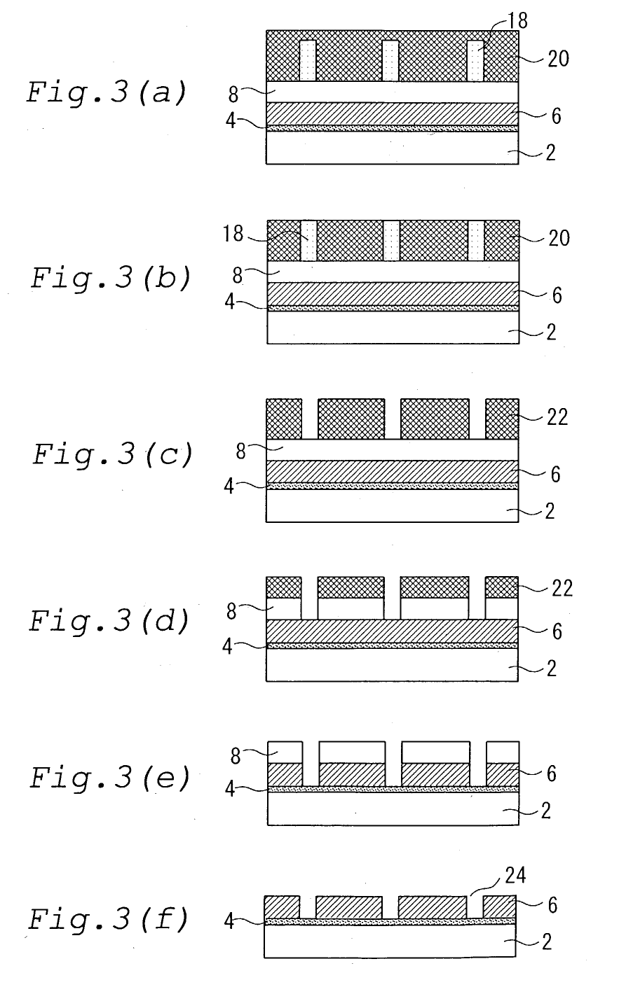

FIG. 1 is a flowchart illustrating a manufacturing method of a semiconductor device according to a first embodiment of the present invention. FIG. 2 includes FIGS. 2(a) to (d), which are schematic cross-sectional views of a semiconductor device as it is formed, illustrating the first several processes of the manufacturing method of the first embodiment. FIG. 3 includes FIGS. 3(a) to (f), which are also schematic cross-sectional views of the semiconductor device as it is formed, illustrating the subsequent processes.

According to the first embodiment, a space pattern is formed by performing the following sequential steps. A resist pattern is formed on a substrate; an SOG film is coated on the resist pattern; an SOG film reversal pattern which is a reverse tone image of the resist pattern is formed; and each film of the substrate is etched using the reversal pattern as a mask, completing the space pattern. It should be noted that as used in this specification, the term “space pattern” refers to a pattern formed using narrow grooves, while the term “line pattern” refers to a pattern formed using narrow strips (lines). The term “dot pattern” refers to a pattern formed using small points.

Description will be made below of the manufacturing method of a semiconductor device according to the first embodiment of the present invention with reference to FIGS. 1 to 3.

First of all, as shown in FIG. 2(a), each necessary film is formed on a silicon substrate 2 at steps S2 to S8. Specifically, according to the first embodiment, a silicon oxide film 4 is formed on the silicon substrate 2 to a thickness of 15 nm at step S2. A polysilicon film 6 is formed on the silicon oxide film 4 to a thickness of 100 nm at step S4. Then, an organic antireflective film 8 is formed to a thickness of 85 nm at step S6. After that, baking is carried out at 200° C. for 90 seconds at step S8.

Then, a resist pattern is formed at steps S10 to S18. Specifically, as shown in FIG. 2(b), an ArF resist 10 is formed on the antireflective film 8 to a thickness of 300 nm at step S10. As the ArF resist 10, the first embodiment uses a positive type resist whose portions subjected to irradiation of exposure light are removed in the development process. After applying the ArF resist 10, baking is carried out at 130° C. for 60 seconds at step S12.

Then, exposure is carried out using as a mask a reticle 12 having a wiring pattern formed thereon at step S14. The reticle 12 is used to form a space pattern in the polysilicon film 6 at a last step. Therefore, the (wiring) pattern is formed such that it corresponds to the space (pattern) to be formed and does not allow the transmission of the exposure light. The aligner is of a scanner type and uses ArF excimer laser having a wavelength of 193 nm as its exposure light source. The illumination conditions are such that a “⅔ annular illumination aperture” whose numerical aperture (NA) is 0.70 is used in an off-axis method.

Then, PEB (Post-Exposure Bake) is performed at 130° C. for 60 seconds at step S16. After that, a development process is carried out at step S18, as shown in FIG. 2(c). Specifically, a 2.38% by weight aqueous solution of TMAH (tetramethylammonium hydroxide) is used to carry out the development for 60 seconds. This process forms a resist pattern 16, which is a line pattern, on the organic antireflective film 8. Then, as shown in FIG. 2(d), baking is carried out at 200° C. for 120 seconds at step S20. Thus, a resist pattern 18 is formed through baking.

It should be noted that the line size of the resist pattern 18 formed in this process is approximately 100 nm.

Then, an SOG film reversal pattern is formed at steps S22 to S28.

Specifically, as shown in FIG. 3(a), an SOG (spin-on glass) film 20 is formed at step S22. The SOG film 20 is made of polysiloxane (SiOₓ). The SOG film 20 is formed on the organic antireflective film 8 and the resist pattern 18 formed on the antireflective film 8 such that the SOG film 20 covers the resist pattern 18. After that, baking is carried out at 200° C. for 120 seconds at step S24.

Then, as shown in FIG. 3(b), the surface of the SOG film 20 is flattened at step S26. Specifically, in the flattening of the surface of the SOG film 20, the surface is etched by means of dry etching until the tops of the resist pattern 18 are exposed.

Then, as shown in FIG. 3(c), the resist pattern 18 is etched using the SOG film 20 as a mask at step S28. With this process, an SOG film reversal pattern 22, which is a reverse tone image of the resist pattern 18, can be obtained.

After that, some films are etched and/or removed at steps S30 to S36.

Specifically, as shown in FIG. 3(d), the organic antireflective film 8 is etched using the SOG film reversal pattern 22 as a mask at step S30.

Then, as shown in FIG. 3(e), the polysilicon film 6 is etched at step S32, and the SOG film 20 is removed at step S34. Furthermore, as shown in FIG. 3(f), the organic antireflective film 8 is removed at step S36.

Thus, a space pattern 24 having a size of approximately 100 nm is formed in the polysilicon film 6 on the silicon substrate 2.

As described above, according to the first embodiment, after a resist pattern is formed, an SOG film reversal pattern is formed. Then, underlayer films are etched using the SOG film reversal pattern as a mask to form a pattern. With this arrangement, it is possible to accurately form a pattern whose size is smaller than the maximum resolution size without causing “falling down” of the pattern, which cannot be achieved by use of an ordinary resist pattern alone.

It should be noted that according to the first embodiment described above, the resist pattern 16 is formed using the positive type ArF resist 10 and, as a mask, the reticle 12 having a portion which corresponds to the space portion of a space pattern and which does not allow the transmission of the exposure light. However, the present invention is not limited to formation of this specific type of fine pattern (space pattern). The present invention can be applied to formation of a dot pattern or a line pattern.

For example, a line pattern which is a reverse image of the space pattern 24 can be formed by use of the reticle 12 used in the first embodiment and a negative type resist. Thus, both a fine line pattern and a fine space pattern can be formed by appropriately selecting a reticle and a resist for each type of pattern and performing steps S2 to S36 of the first embodiment.

It should be further noted that according to the first embodiment, baking is carried out at high temperature at step S20 after the formation of the resist pattern 16. This prevents the resist from “dissolving into” the SOG film when the SOG film is applied, making it possible to use both negative type and positive type resists.

Still further according to the first embodiment described above, a fine pattern is formed in the polysilicon film 6 formed on the silicon substrate 2. However, the present invention (which relates to a manufacturing method of a semiconductor device) is not limited to the case where a fine pattern is formed in a polysilicon film. The present invention can be applied to the case where a fine pattern is formed in another film or the silicon substrate as necessary.

Still further according to the first embodiment, an organic antireflective film is formed to a film thickness of 85 nm. However, the present invention is not limited to this specific thickness if it is possible to ensure sufficient etching selectivity with the SOG film. For example, the pattern formation can be achieved even when the underlayer organic film has a film thickness of 300 nm to 500 nm depending on the film type and thickness of the film on the substrate or of the substrate to be processed.

Still further according to the first embodiment described above, etchback is carried out by means of dry etching to flatten the SOG film 20. However, the present invention is not limited to this specific type of planerization method. Another planerization method such as CMP can be employed.

Second Embodiment

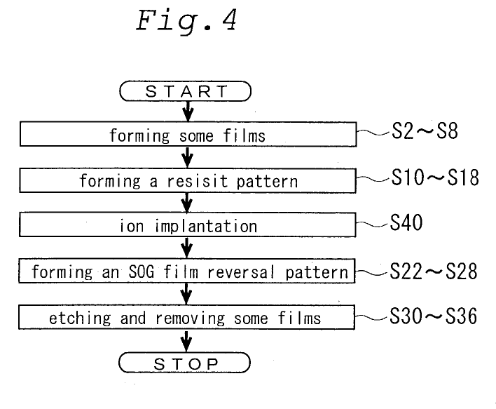

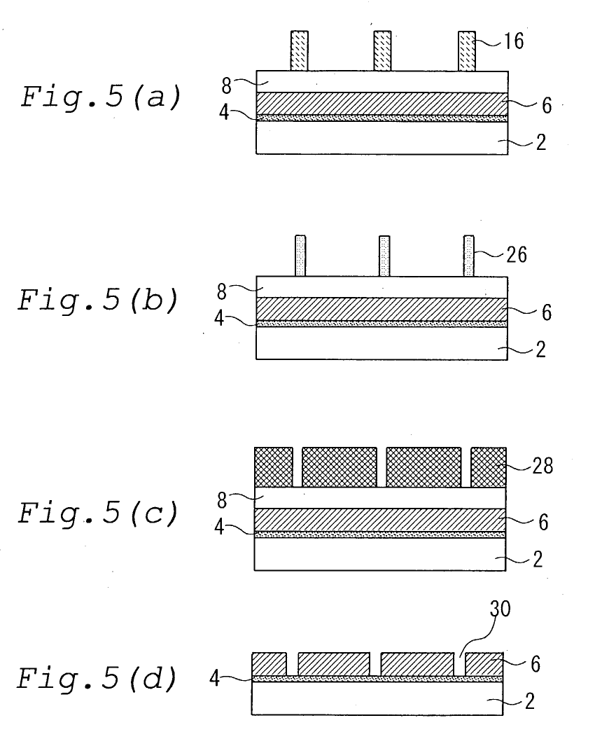

FIG. 4 is a flowchart illustrating a manufacturing method of a semiconductor device according to a second embodiment of the present invention. FIG. 5 includes FIGS. 5(a) to (d), which are schematic cross-sectional views of a semiconductor device as it is formed, illustrating the processes for forming a fine pattern according to the second embodiment.

According to the second embodiment, as in the first embodiment, a pattern is formed by performing the following sequential steps. A resist pattern which is a line pattern is formed; an SOG film is formed; an SOG film reversal pattern which is a reverse tone image of the resist pattern is formed; and underlayer films of the substrate are etched using the reversal pattern as a mask, completing the target pattern. However, the second embodiment is different from the first embodiment in that it includes a step of reducing the size of the above formed resist pattern such that a space pattern including narrower spaces can be formed in an underlayer film.

Detailed description will be made below of the manufacturing method of a semiconductor device according to the second embodiment of the present invention with reference to FIGS. 4 and 5.

First of all, as shown in FIG. 5(a), each film is formed on the silicon substrate 2 at steps S2 to S8, as in the first embodiment. Furthermore, the resist pattern 16 is formed at steps S10 to S18. In these steps, the exposure and development conditions, etc. for formation of the resist pattern are the same as those for the first embodiment. Therefore, the line width of the formed resist pattern 16 is equal to that in the first embodiment, that is, 100 nm.

Then, as shown in FIG. 5(b), the resist pattern 16 is implanted with ions at step S40. The ion implantation is carried out by use of Ar ions at 1×10¹⁶/cm² and 50 KeV. When the resist pattern 16 has been implanted with the ions, it contracts. As a result, the resist pattern 16, whose line width is 100 nm, is reduced into a resist pattern 26, whose line width is 50 nm.

Then, as shown in FIG. 5(c), an SOG film reversal pattern 28 is formed at steps S22 to S28. Specifically, as in the first embodiment, the SOG film reversal pattern 28 is formed by performing the following processing: formation of the SOG film 20 at step S22; baking at step S24; etchback at step S26; and etching of the resist pattern 26 at step S28. After that, as in the first embodiment, some films are etched and/or removed at steps S30 to S36 to obtain a space pattern 30 having a size of 50 nm in the polysilicon film 6.

As described above, according to the second embodiment, the resist pattern 16 is implanted with ions so as to reduce the line width of the pattern. Therefore, it is possible to form a pattern whose size is smaller than the maximum resolution size and thereby contribute to pattern miniaturization. Furthermore, the SOG film reversal pattern 28 is formed and used as a mask for etching underlayer films, making it possible to prevent occurrence of “falling down” of a pattern even when its width is reduced. Therefore, the fine space pattern 30 can be formed in the polysilicon film 6 more reliably.

Since the other portions of the second embodiment are the same as those of the first embodiment, their explanation will be omitted.

In the above description, the second embodiment is described as applied to formation of a space pattern. However, the present embodiment is not limited to formation of this specific type of pattern (space pattern). The present embodiment can also be applied to formation of a line pattern, as is the case with the first embodiment.

Further in the above description, the resist pattern 16 is implanted with ions to produce the resist pattern 26 whose line width is narrower than that of the resist pattern 16. However, the present invention is not limited to this specific method to reduce the line width. Another method such as electron beam curing or light curing may be employed. It should be noted that in the case of electron beam curing, preferable conditions are such that: 25° C.; nitrogen atmosphere; 4.0 KeV; 12 mA; and electron beam irradiation with a dose amount of 200 μC/cm². In the case of light curing, on the other hand, preferable conditions are such that: 110° C.; air atmosphere; and irradiation of light having a wavelength of between 250 nm and 450 nm for 1 min, for example.

It should be noted that performing ion implantation, electron beam curing, or light curing on the resist pattern can prevent the resist pattern from “dissolving” (into the SOG film) when the resist pattern is coated with the SOG film, making it possible to accurately form the SOG film reversal pattern.

It should be further noted that according to the present invention, ions to be implanted in the resist pattern are not limited to Ar ions. For example, helium, nitrogen, boron, phosphor, arsenic, germanium, or other types of ions may be used.

Still further, in the above description of the second embodiment, etchback is carried out by means of dry etching to flatten the SOG film 20. However, the present embodiment is not limited to this specific type of planerization method. Another planerization method such as CMP can be employed, as is the case with the first embodiment.

Third Embodiment

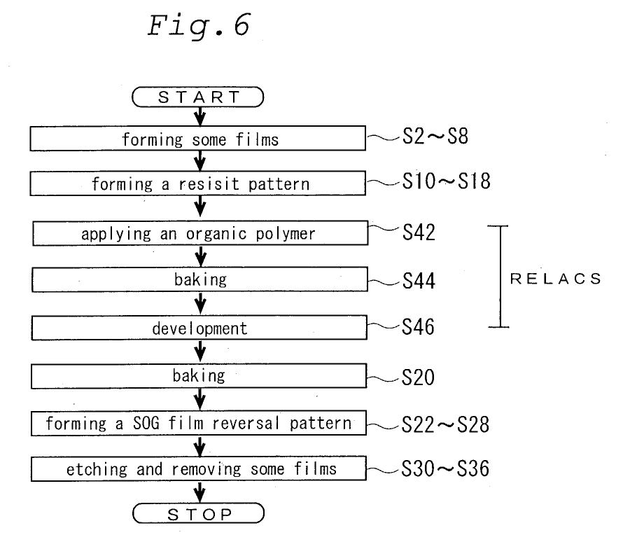

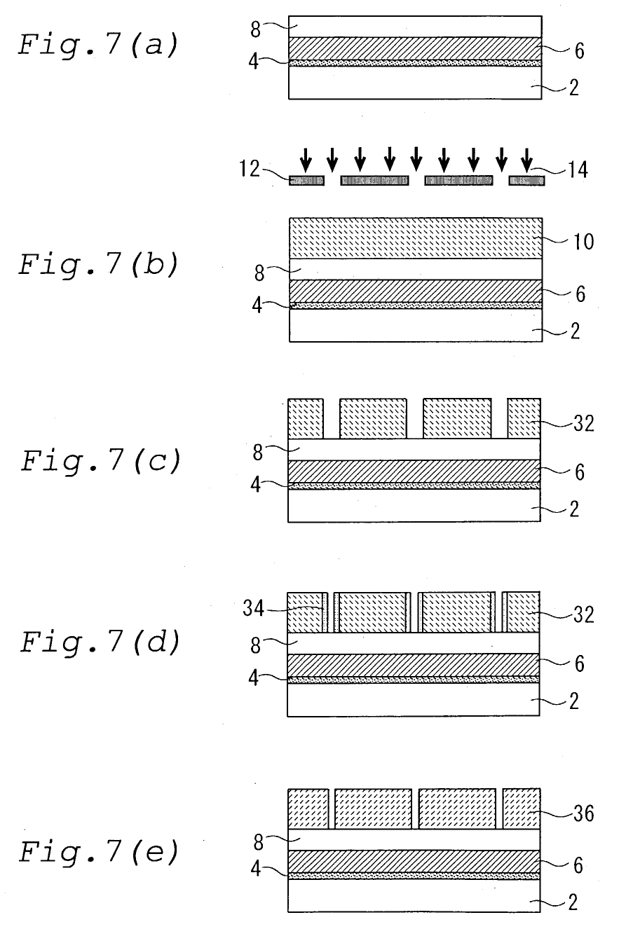

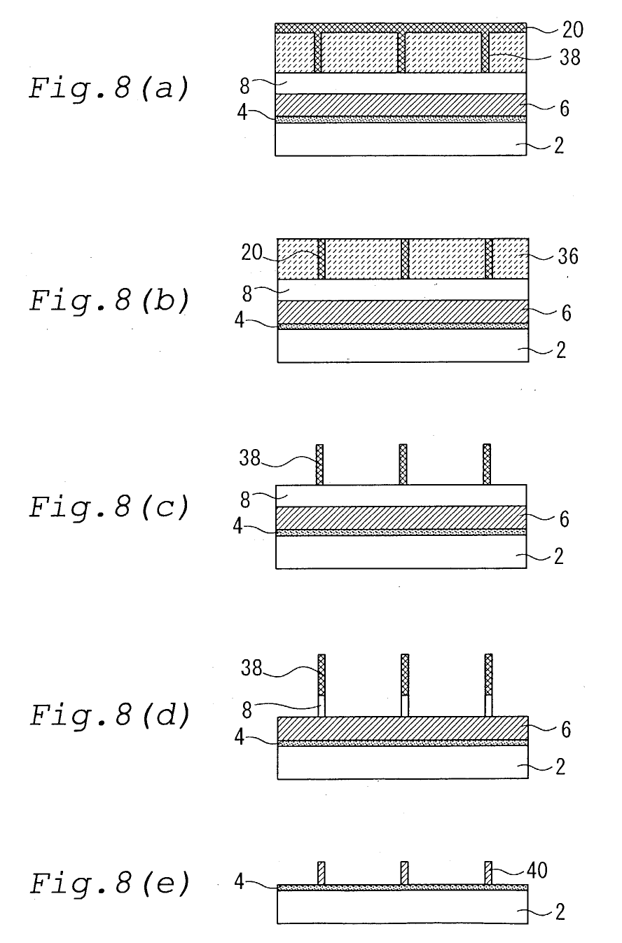

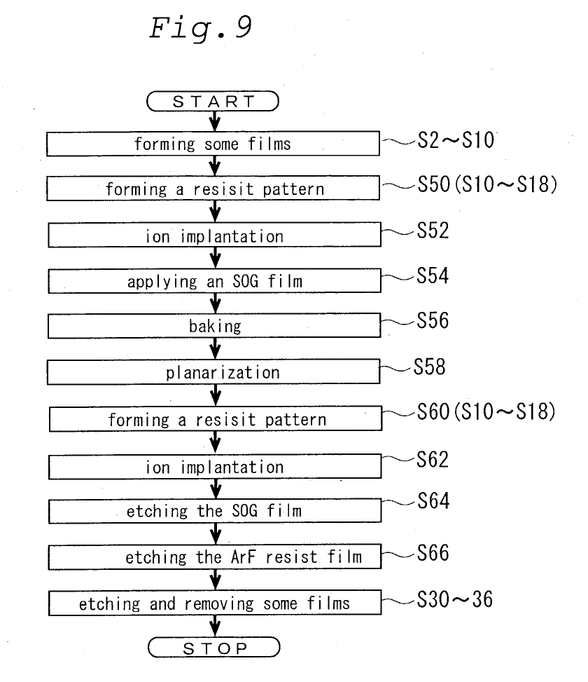

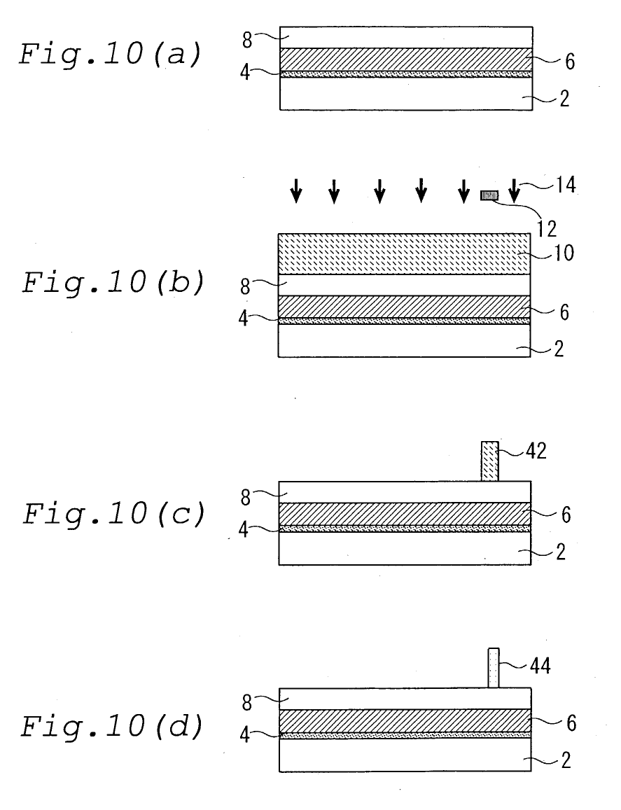

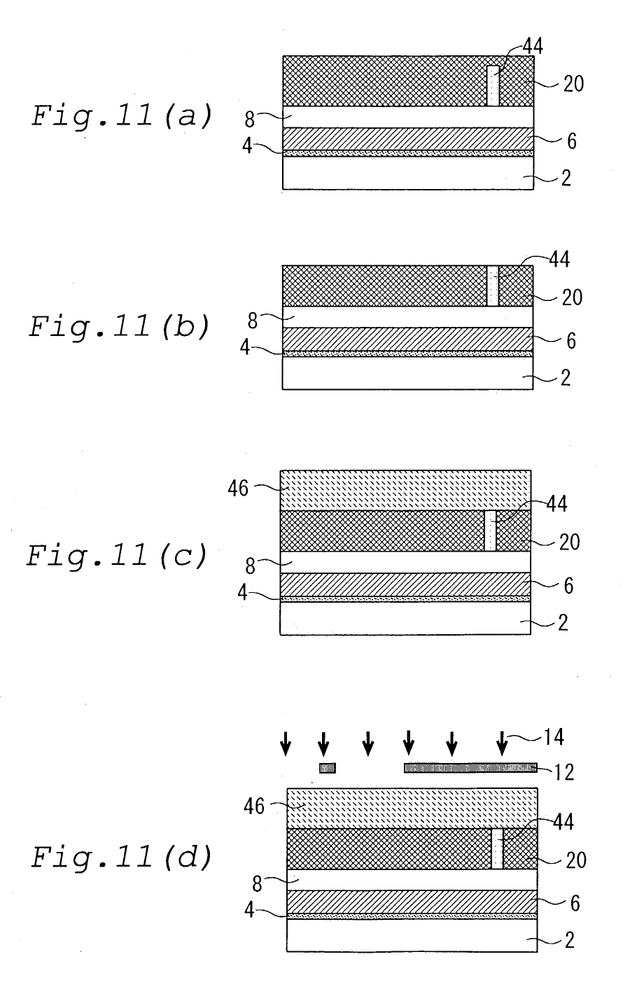

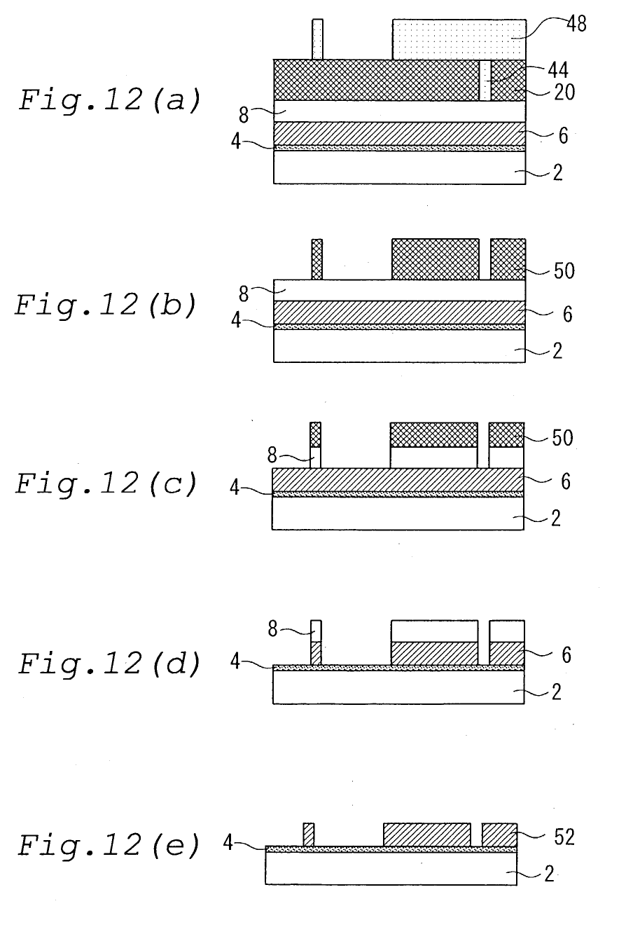

FIG. 6 is a flowchart illustrating a manufacturing method of a semiconductor device according to a third embodiment of the present invention. FIG. 7 includes FIGS. 7(a) to (e), which are schematic cross-sectional views of a semiconductor device as it is formed, illustrating the first several processes for forming a fine pattern according to the third embodiment. FIG. 8 includes FIGS. 8(a) to (e), which are also schematic cross-sectional views of the semiconductor device as it is formed, illustrating the subsequent processes for forming the fine pattern.

According to the third embodiment, it is a fine line pattern that is formed in the polysilicon film 6, which is different from the case explained in the above descriptions of the first and second embodiments.

Description will be made below of the manufacturing method of a semiconductor device according to the third embodiment with reference to FIGS. 6 to 8.

First of all, as shown in FIG. 7(a), each film is formed on the silicon substrate 2 at steps S2 to S8, as in the first embodiment. Then, as shown in FIGS. 7(b) and (c), a resist pattern 32 is formed at steps S10 to S18. In these steps, the exposure and development conditions are the same as those for the first embodiment described above. However, the reticle 12 of the third embodiment is different from that of the first embodiment in that it has a portion which corresponds to the line portion of a line pattern to be formed in the polysilicon film and which allows the transmission of the exposure light. The ArF resist 10 of the third embodiment is of a positive type, as in the first embodiment. With this arrangement, the resist pattern 32, which is a space pattern, is formed on the antireflective film 8, as shown in FIG. 7(c).

Then, as shown FIGS. 7(d) and (e), a framing process is performed on the resist pattern 32 at steps S42 to S46. In this case, the RELACS (Resolution Enhancement Lithography Assisted By Chemical Shrink) process is used. Specifically, as shown in FIG. 7(d), the sidewalls of the space portion of the resist pattern 32 are coated with an organic polymer 34 containing a crosslinking agent at step S42. After that, baking and development processes are carried out at steps S44 and S46, respectively. Thus, a resist pattern 36 having a space width of 100 nm is obtained, as shown in FIG. 7(e).

Then, as in the first embodiment, baking is carried out at 200° C. for 120 seconds at step S20, and an SOG film reversal pattern 38 is formed at steps S22 to S28. Specifically, as shown in FIG. 8(a), the SOG film 20 is formed such that it fills the space portion of the resist pattern 36 and furthermore covers the surface of the resist pattern 36 at step S22. After that, baking is carried out at step S24. Then, as shown in FIG. 8(b), etchback is carried out by means of dry etching to flatten the surfaces of the SOG film 20 and the resist pattern 36 at step S26. Furthermore, as shown in FIG. 8(c), the resist pattern 36 is removed at step S28, forming the SOG film reversal pattern 38, which is a line pattern.

Then, as shown in FIGS. 8(d) and (e), some films are etched and/or removed at steps S30 to S36, as in the first embodiment. With this, a fine line pattern 40 can be formed in the polysilicon film 6, as shown in FIG. 8(e). The line width of the formed line pattern 40 is 100 nm.

As described above, according to the third embodiment, the resist pattern 32 is framed to produce the finer resist pattern 36, making it possible to form the finer line pattern 40.

Since the other portions of the third embodiment are the same as those of the first embodiment, their explanation will be omitted.

In the above description, the third embodiment is described as applied to formation of a line pattern. However, the present embodiment is not limited to formation of this specific type of pattern (line pattern). The present embodiment can also be applied to formation of a fine dot pattern.

Further in the above description of the third embodiment, the RELACS process is used to make the pattern finer. However, the present invention is not limited to this specific framing method. For example, another framing method may be used, or the framing process itself may not be carried out.

It should be noted that the RELACS process described above uses an organic polymer. The organic polymer does not “dissolve into” the SOG film 20 even when the SOG film 20 is directly applied at the subsequent step S22, making it possible to form a reversal pattern in a simple process.

Still further, in the above description of the third embodiment, the SOG film 20 is flattened by means of dry etching. However, the present invention is not limited to this specific type of planerization method. Another planerization method such as CMP can be employed, as is the case with the first embodiment.

Fourth Embodiment

FIG. 9 is a flowchart illustrating a manufacturing method of a semiconductor device according to a fourth embodiment of the present invention. FIG. 10 includes FIGS. 10(a) to (d), which are schematic cross-sectional views of a semiconductor device as it is formed, illustrating the first several processes for forming a fine pattern according to the fourth embodiment. FIG. 11 includes FIGS. 11(a) to (d), which are also schematic cross-sectional views of the semiconductor device as it is formed, illustrating the subsequent several processes for forming the fine pattern. FIG. 12 includes FIGS. 12(a) to (e), which are also schematic cross-sectional views of the semiconductor device as it is formed, illustrating the last several processes for forming the fine pattern.

The fourth embodiment is applied to formation of a pattern which includes both a fine line pattern and a fine space pattern. According to the present embodiment, a pattern including line and space patterns is formed by performing the following sequential steps. A resist pattern for a space (or line) pattern is formed on a substrate; an SOG film is formed on the space (or line) pattern; a resist pattern for a line (or space) pattern is formed on the SOG film as an upper layer; the SOG film is etched using the resist pattern for the line (or space) pattern as a mask; the resist pattern for the space (or line) pattern is removed, thereby forming an SOG film reversal pattern; and the substrate is etched using the SOG film reversal pattern as a mask, completing the pattern including both line and space patterns.

Detailed description will be made below of the manufacturing method of a semiconductor device according to the fourth embodiment with reference to FIGS. 9 to 12.

First of all, as shown in FIG. 10(a), each film is formed on the silicon substrate 2 at steps S2 to S8. Then, as shown in FIGS. 10(b) and (c), a resist pattern 42 is formed at step S50 by performing processes similar to those at steps S10 to S18 of the first embodiment. The reticle 12 used at this step has a portion which corresponds to a space to be formed in the polysilicon film 6 at a last step and which does not allow the transmission of the exposure light. The exposure and development conditions are the same as those for the first embodiment.

Then, as shown in FIG. 10(d), the resist pattern 42 is implanted with ions at step S52. The ion implantation at this step is performed under the same conditions as those for step S40 of the second embodiment. With this, a resist pattern 44 having a reduced width (50 nm) can be obtained.

Then, as shown in FIG. 11(a), the SOG film 20 is formed such that it covers the resist pattern 44 at step S54, and baking is carried out at 200° C. for 120 seconds at step S56. Furthermore, as shown in FIG. 11(b), the surface of the SOG film 20 is flattened until the top of the resist pattern 44 is exposed at step S58. It should be noted that etchback by means of dry etching is used for the planerization at this step.

Then, a resist pattern is formed on the SOG film 20 at step S60 by performing processes similar to those at steps S10 to S18 of the first embodiment. Specifically, as shown in FIG. 11(c), an ArF resist film 46 is coated on the SOG film 20 at step S10, and baking is carried out at 130° C. for 60 seconds at step S12. After that, as shown in FIG. 11(d), ArF excimer laser light is irradiated through the reticle 12 to carry out exposure at step S14. The reticle 12 used at this step has portions which correspond to the line and space portions (of a pattern) to be formed in the polysilicon film 6 at a last step and which does not allow the transmission of the exposure light. After the exposure, baking is carried out at 130° C. for 60 seconds at step S16 before development is performed at step S18. It should be noted that the exposure and development conditions are the same as those for the first embodiment. Thus, the resist pattern is formed on the SOG film 20.

The portion of the thus formed resist pattern which is to become a line pattern is implanted with ions at step S62. The ion implantation is performed under the same conditions as those for step 40 of the second embodiment. As a result, a resist pattern 48 is obtained whose line pattern portion has a line width of 50 nm (reduced from 100 nm).

It should be noted that the resist pattern 48 formed at the above step and the resist pattern 44 each include a line pattern at a different position, and furthermore the resist pattern 48 has a portion with an appropriate width which covers the line portion (pattern) of the resist pattern 44.

Then, the SOG film 20 is etched using the resist pattern 48 as a mask at step S64. After that, the resist pattern 44 is etched using the SOG film 20 as a mask at step S66, as in the first embodiment. As a result, an SOG film reversal pattern 50 is formed, as shown in FIG. 12(b).

Then, as shown in FIGS. 12(c) to (e), some films are etched and/or removed using the SOG film reversal pattern 50 as a mask at steps S30 to S36, as in the first embodiment. As a result, a pattern 52 including both a fine line pattern and a fine space pattern is formed in the polysilicon film 6.

Thus, it is possible to form both a fine line pattern and a fine space pattern at the same time. Therefore, the present embodiment can be applied to formation of logic patterns, which are becoming finer. According to the present embodiment, since the resist pattern is implanted with ions, it is possible to form a finer pattern while preventing the resist from “dissolving into” the SOG film. Furthermore, since the SOG film reversal pattern is formed before the underlayer films are etched, “falling down” of a pattern can be prevented even when the resist pattern is made finer, making it possible to more reliably form a fine pattern.

Since the other portions of the fourth embodiment are the same as those of the first to third embodiments, their explanation will be omitted.

It should be noted that according to the fourth embodiment, ion implantation is carried out after each resist pattern is formed. However, the present invention is not limited to this specific arrangement. Each resist pattern may be baked as it is without performing ion implantation. Even with this arrangement (without ion implantation), an SOG film reversal pattern can be formed while preventing the resists from “dissolving into” SOG, making it possible to prevent “falling down” of a pattern and reliably form line and space patterns.

Further, as explained in the description of the second embodiment, electron beam curing, light curing, etc. may be performed on the resist patterns, instead of ion implantation. Also with these treatments, it is possible to reduce the line width of the resist patterns while preventing the resists from “dissolving into” the SOG film.

Still further, according to the prevent invention, ions to be implanted in the resist patterns are not limited to Ar ions. For example, helium, nitrogen, boron, phosphor, arsenic, germanium, or other types of ions may be used.

Still further, according to the fourth embodiment, after a space pattern is formed in the SOG film, the resist pattern is etched to form a line pattern, thereby forming an SOG film reversal pattern. However, a space pattern portion may be formed after formation of a line pattern in the SOG film by selecting an appropriate reticle and resist. In such a case, after a resist pattern for forming the space pattern is formed, the resist pattern may be framed by means of RELACS to reduce its space width.

Still further, according to the fourth embodiment, etchback is carried out by means of dry etching to flatten the SOG film. However, the present invention is not limited to this specific type of planerization method. Another planerization method such as CMP can be employed.

Fifth Embodiment

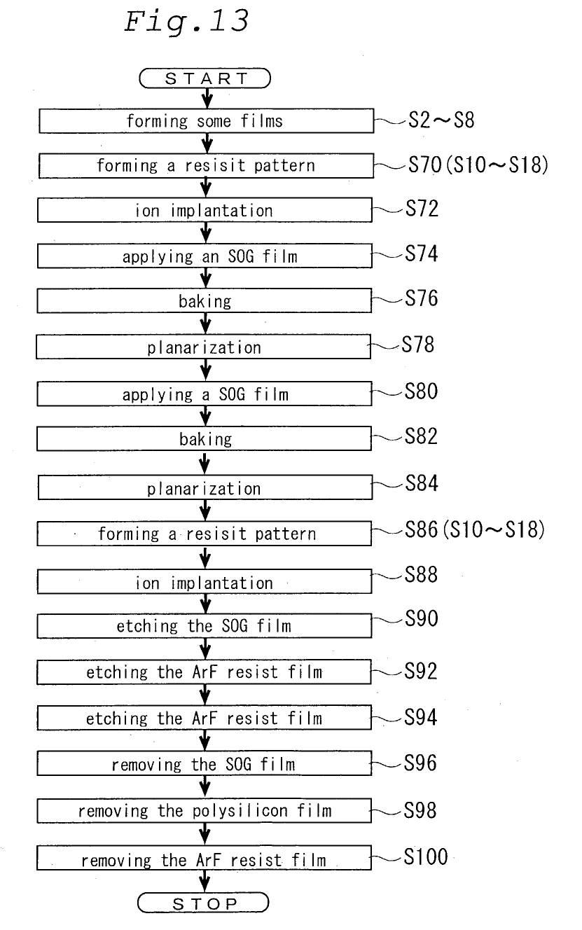

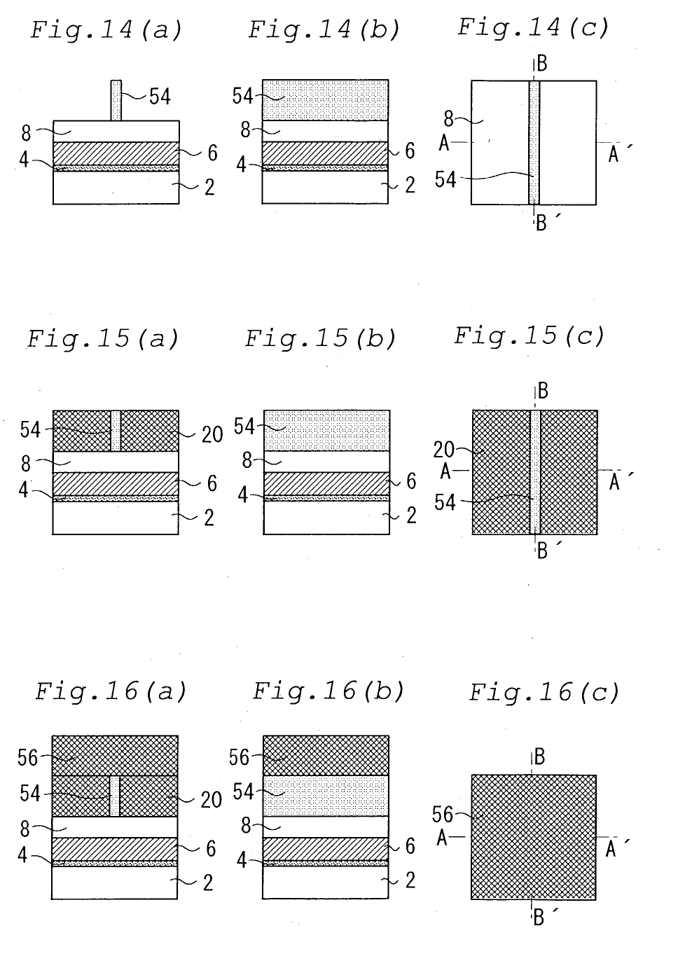

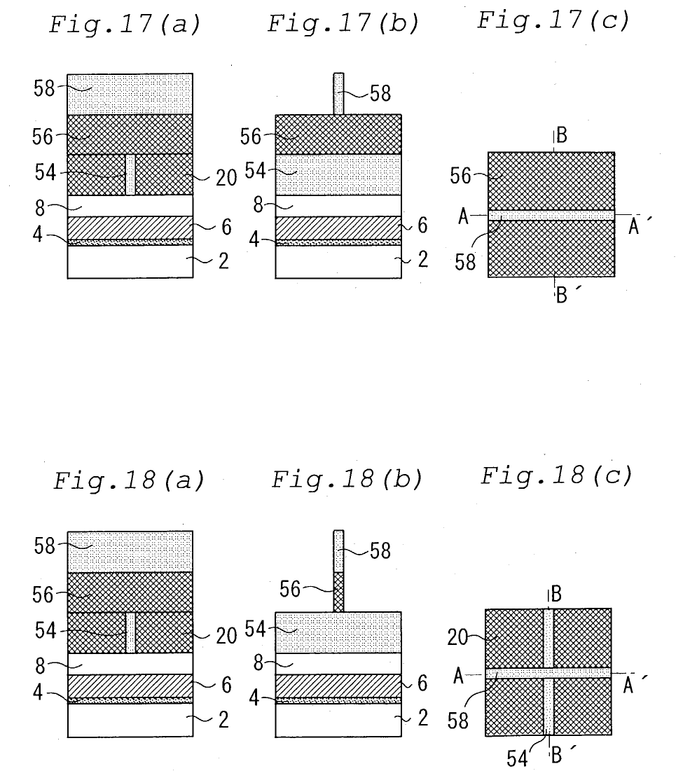

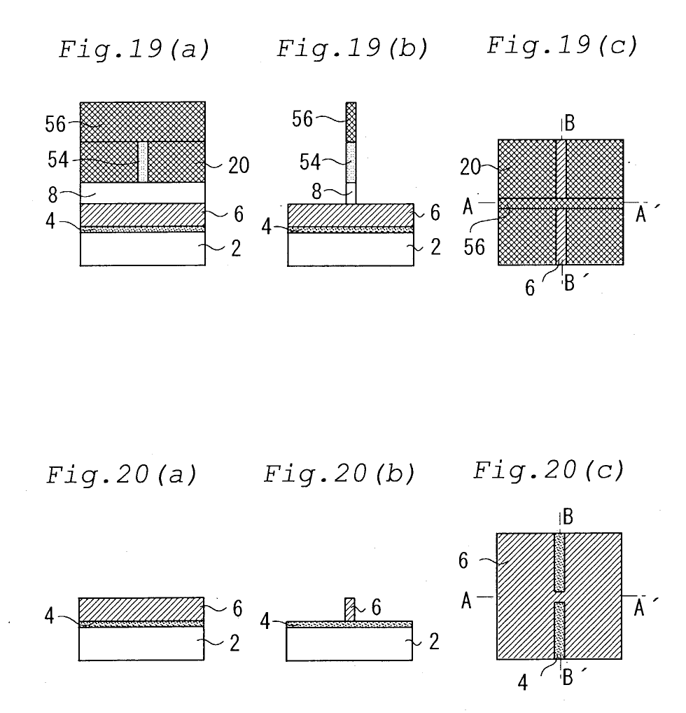

FIG. 13 is a flowchart illustrating a manufacturing method of a semiconductor device according to a fifth embodiment of the present invention. FIGS. 14 to 20 are schematic diagrams illustrating the processes for forming a fine pattern according to the fifth embodiment. Each figure includes 3 subfigures such as FIG. 14(a), (b), and (c) in the case of FIG. 14. In each figure, subfigure (c) is a plan view, and subfigures (a) and (b) are cross-sectional views of what the subfigure (c) shows, taken along line A-A′ and line B-B′, respectively.

Description will be made below of the manufacturing method of a semiconductor device according to the fifth embodiment with reference to FIGS. 13 to 20.

First of all, each film is formed on the silicon substrate 2 at steps S2 to S8, as in the first embodiment. After that, a resist pattern is formed on the antireflective film 8 at step S70 by performing processes similar to those at steps S10 to S18 of the first embodiment. Then, as shown in FIG. 14, the resist pattern is implanted with ions to produce a resist pattern 54 having a size of 50 nm at step S72. The ion implantation at this step is performed under the same conditions as those for step S40 of the second embodiment.

Then, the SOG film 20 is formed on the resist pattern 54 at step S74, and baking is carried out at 200° C. for 120 seconds at step S76. After that, etchback is carried out by means of dry etching to flatten the SOG film 20 until the top of the resist pattern 54 is exposed at step S78, as shown in FIG. 15.

Then, as shown in FIG. 16, an SOG film 56 is formed on the SOG film 20 at step S80, and baking is carried out at 200° C. for 120 seconds at step S82. Furthermore, etchback is carried out by means of dry etching to flatten the surface of the SOG film 56 at step S84.

Then, a resist pattern 58 is formed on the SOG film 56 at step S86 by performing processes similar to those at steps S10 to S18 of the first embodiment. It should be noted that the exposure and development conditions at this step are the same as those for the first embodiment. After that, as shown in FIG. 17, the resist pattern is implanted with ions to produce a resist pattern 58 having a size of 50 nm (reduced from the original resist pattern size 100 nm) at step S88. It should be noted that the ion implantation at this step is performed under the same conditions as those for the ion implantation at step S40 of the second embodiment.

It should be further noted that as shown in FIGS. 14 to 18 the resist pattern 54 is a line pattern formed in the direction of line B-B′ while the resist pattern 58 is a line pattern formed in the direction of line A-A′. That is, as viewed from the top, the resist pattern 54 and the resist pattern 58 are line patterns intersecting each other at nearly a right angle.

Then, as shown in FIG. 18, the SOG film 56 is etched using the resist pattern 58 as a mask at step S90. Furthermore, as shown in FIG. 19, the resist pattern 54 is etched using the SOG film 56 as a mask at step S92, and subsequently the organic antireflective film 8 is etched at step S94. As a result, the portion of the resist pattern 54 whose upper surface is not covered with the SOG film 56 is removed, exposing the polysilicon film 6 there.

Then, the SOG films are removed at step S96, and the polysilicon film 6 is etched using the organic antireflective film 8 as a mask at step S98. After that, as shown in FIG. 20, the organic antireflective film 8 is removed at step S100, forming a space pattern 60 and a portion which divides the space pattern 60 into two portions.

With the above arrangement, it is possible to form a fine space pattern while preventing its edge portions from “retreating”.

Since the other portions of the fifth embodiment are the same as those of the first to fourth embodiments, their explanation will be omitted.

It should be noted that according to the fifth embodiment, the resist patterns 54 and 58 are formed as a result of reducing the line widths of their original resist patterns through ion implantation at steps S74 and S88. However, the present invention is not limited to this specific method (ion implantation). The line widths of the resist patterns may be reduced by means of electron beam curing, light curing, etc., instead of ion implantation. Furthermore, the ion implantation process, etc. may not be carried out; that is, resist patterns whose pattern widths are equal to those formed at a last step are baked as they are without reducing their line widths. Performing ion implantation, electron beam curing, light curing, high-temperature baking, etc. on the resist patterns can prevent the resists from “dissolving into” the SOG films.

It should be noted that when electron beam curing or light curing is used for the fifth embodiment instead of ion implantation, the conditions explained in the description of the second embodiment may be employed.

Further, in the above description of the present embodiment, the resist patterns are implanted with Ar ions. However, the present invention is not limited to this specific type of ions (Ar ions). For example, helium, nitrogen, boron, phosphor, arsenic, germanium, or other types of ions may be used.

Still further, according to the present embodiment, the SOG films are etched back by means of dry etching. However, the present invention is not limited to this specific type of planerization method. Another planerization method such as CMP can be employed.

Sixth Embodiment

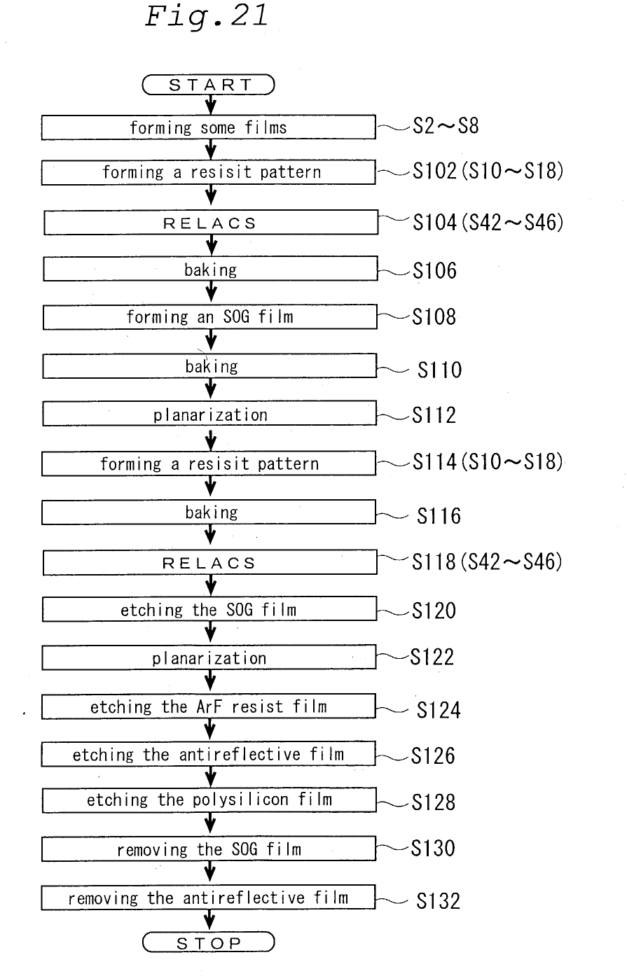

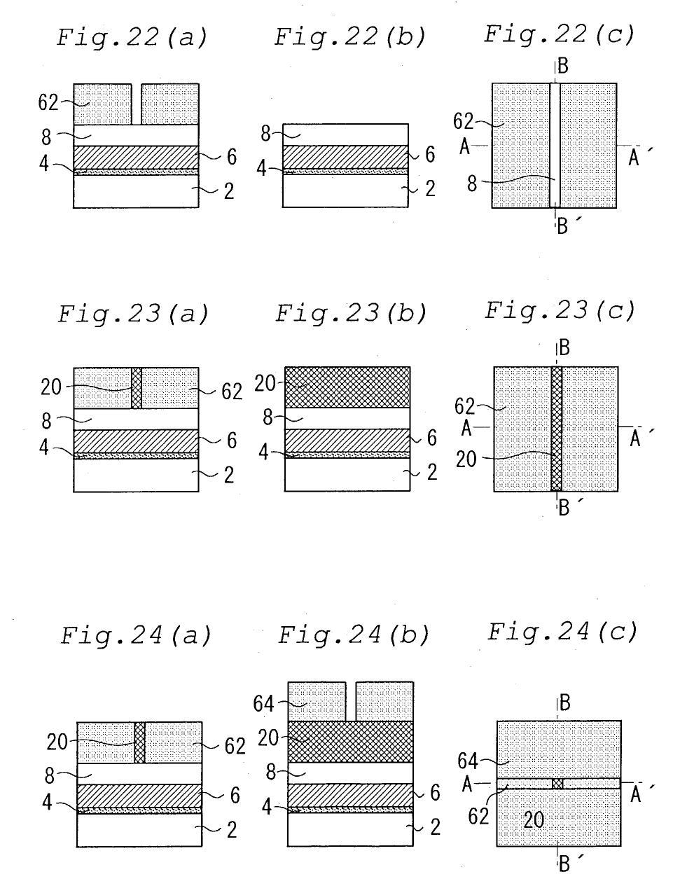

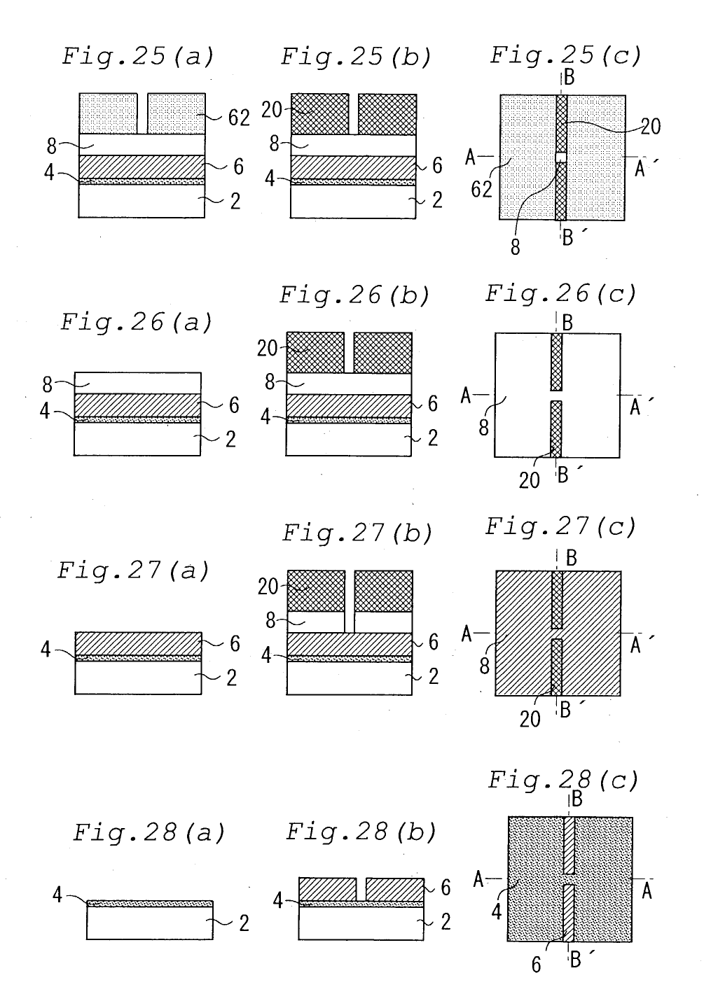

FIG. 21 is a flowchart illustrating a manufacturing method of a semiconductor device according to a sixth embodiment of the present invention. FIGS. 22 to 28 are schematic diagrams illustrating the processes for manufacturing a semiconductor device according to the sixth embodiment. Each figure includes 3 subfigures such as FIG. 22(a), (b), and (c) in the case of FIG. 22. In each figure, subfigure (c) is a plan view, and subfigures (a) and (b) are cross-sectional views of what the subfigure (c) shows, taken along line A-A′ and line B-B′, respectively.

Description will be made below of the manufacturing method of a semiconductor device according to the sixth embodiment with reference to FIGS. 21 to 28.

First of all, as in the third embodiment, each film is formed on the silicon substrate 2 at step S2 to S8, and subsequently, a resist pattern is formed at step S102 by performing processes similar to those at steps S10 to S18. Furthermore, the resist pattern is framed by means of RELACS at step S104 by performing processes similar to those at steps S42 to S46. As a result, a resist pattern 62 having a space width of 100 nm is obtained, as shown in FIG. 22.

Then, after baking is carried out at 200° C. for 120 seconds at step S106, the SOG film 20 is formed such that it fills the space portion of the resist pattern 62 and covers the upper surface of the resist pattern 62 at step S108, and further baking is carried out at 200° C. for 120 seconds at step S110. After that, etchback is carried out by means of-dry etching to flatten the surfaces of the SOG film 20 and the resist pattern 62 until the top of the resist pattern 62 is exposed at step S112.

Then, another resist pattern is formed at step S114 by performing processes similar to those at steps S10 to S18 of the first embodiment. The exposure and development conditions at this step are the same as those for the first embodiment. Furthermore, baking is carried out at 130° C. for 60 seconds at step S116, and this resist pattern is framed by means of RELACS at step S118 by performing processes similar to those at steps S42 to S46 of the third embodiment. As a result, a resist pattern 64 having a space width of 100 nm is obtained, as shown in FIG. 24.

It should be noted that as shown in FIGS. 22 and 24, the resist pattern 62 is a space pattern formed in the direction of line B-B′ while the resist pattern 64 is a space pattern formed in the direction of line A-A′. That is, the resist pattern 62 and the resist pattern 64 are space patterns intersecting each other at nearly a right angle.

Then, as shown in FIG. 25, the SOG film 20 is etched using the resist pattern 64 as a mask at step S120.

After that, the resist pattern 64 is removed by means of dry etching at step S122, exposing the surface of the SOG film 20. Then, as shown in FIG. 26, the resist pattern 62 is etched using the SOG film 20 as a mask at step S124. Furthermore as shown in FIG. 27, the organic antireflective film 8 is etched using the SOG film 20 as a mask at step S126.

Then, the polysilicon film 6 is etched using the SOG film 20 as a mask at step S128. After that, the SOG film 20 and the organic antireflective film 8 are removed at steps S130 and S132, respectively. As a result, a line pattern with a size of 100 nm and a space pattern also with a size of 100 nm which intersects the line pattern are formed in the polysilicon 6, as shown in FIG. 28.

As described above, the sixth embodiment characteristically includes such processes as tone reversal by use of an SOG film, formation of a second resist pattern, and framing by means of RELACS. With this arrangement, it is possible to form a fine line pattern while preventing its edge portions from “retreating”. Furthermore, an organic polymer is used for the framing. Therefore, even when SOG is directly applied at a subsequent step, the “dissolution” of the resist into the SOG can be prevented, making it possible to manufacture a semiconductor device in a simple process.

Since the other portions of the sixth embodiment are the same as those of the first to fifth embodiments, their explanation will be omitted.

It should be noted that in the above description of the sixth embodiment, framing is performed by means of RELACS to produce the resist patterns 62 and 64. However, the present invention is not limited to this specific method. For example, another method for reducing the space width of each pattern may be used, or the framing process itself may not be carried out, depending on the line width to be formed.

Further, according to the sixth embodiment, the SOG film is etched back by means of dry etching. However, the present invention is not limited to this specific type of planerization method. Another planerization method such as CMP can be employed.

It should be noted that the substrate and the underlayer film described in the appended claims correspond to, for example, the silicon substrate 2 and the polysilicon film 6, respectively, of the first to sixth embodiments.

Further, the resist pattern described in the appended claims corresponds to, for example, the resist pattern 16 or 18 of the first, second, and fourth embodiments, or the resist pattern 32 of the third embodiment or the resist pattern 62 of the sixth embodiment. Still further, the spin-on glass film described in the appended claims corresponds to, for example, the SOG film 20 of the first to fourth and sixth embodiments.

Still further, the upperlayer resist pattern described in the appended claims corresponds to, for example, the resist pattern 48 of the fourth embodiment or the resist pattern 64 of the sixth embodiment.

Still further, the first resist pattern and the second resist pattern described in the appended claims correspond to, for example, the resist pattern 54 and the resist pattern 58, respectively, of the fifth embodiment. Still further, the first spin-on glass film and the second spin-on glass film described in the appended claims correspond to, for example, the SOG film 20 and the SOG film 56, respectively, of the fifth embodiment.

Still further, the underlayer film forming step described in the appended claims corresponds to, for example, step S4 of the first to sixth embodiments, whereas the resist pattern forming step described in the appended claims corresponds to, for example, the set of sequential steps S8 to S10 of the first to fourth embodiments or step S102 of the sixth embodiment. Still further, the spin-on glass film forming step described in the appended claims corresponds to, for example, step S22 of the first to third embodiments, step S54 of the fourth embodiment, or step S108 of the sixth embodiment, whereas the resist pattern removing step described in the appended claims corresponds to, for example, step S28 of the first to third embodiments, step S66 of the fourth embodiment, or step S124 of the sixth embodiment. Still further, the underlayer film etching step described in the appended claims corresponds to, for example, step S32 of the first to fourth embodiments or step S128 of the sixth embodiment.

Still further, the upperlayer resist pattern forming step described in the appended claims corresponds to, for example, step S60 of the fourth embodiment or step S114 of the sixth embodiment, whereas the spin-on glass film etching step described in the appended claims corresponds to, for example, step S64 or step S120.

Still further, the first resist pattern forming step described in the appended claims corresponds to, for example, step S70 of the fifth embodiment, whereas the first spin-on glass film forming step described in the appended claims corresponds to, for example, step S74 of the fifth embodiment. Still further, the planerization step described in the appended claims corresponds to, for example, step S78 of the fifth embodiment. Still further, the second spin-on glass film forming step described in the appended claims corresponds to, for example, step S80 of the fifth embodiment, whereas the second resist pattern forming step described in the appended claims corresponds to, for example, step S86 of the fifth embodiment. Still further, the spin-on glass film etching step described in the appended claims corresponds to, for example, step S90 of the fifth embodiment, whereas the resist pattern etching step described in the appended claims corresponds to, for example, step S92. Still further, the underlayer film etching step described in the appended claims corresponds to, for example, step S98 of the fifth embodiment.

The features and the advantages of the present invention as described above may be summarized as follows.

According to one aspect of the present invention, a pattern is formed in a spin-on glass film using a resist pattern, and then an underlayer film is etched using the spin-on glass film as a mask. Accordingly, it is possible to form a fine line pattern or space pattern in a simple process while preventing occurrence of “falling down” of a pattern.

In another aspect, a first spin-on glass film and a second spin-on glass film are laminated and a pattern is formed in these films. Then an underlayer film is etched using both the first and the second spin-on glass film as a mask. Accordingly it is possible to form a fine space pattern while preventing its edge portions from “retreating”.

Obviously many modifications and variations of the present invention are possible in the light of the above teachings. It is therefore to be understood that within the scope of the appended claims the invention may by practiced otherwise than as specifically described.

The entire disclosure of a Japanese Patent Application No. 2002-341304, filed on Nov. 25, 2002 including specification, claims, drawings and summary, on which the Convention priority of the present application is based, are incorporated herein by reference in its entirety.

1. A method for manufacturing a semiconductor device, comprising:
an underlayer film forming step of forming an underlayer film on a substrate;
a resist pattern forming step of forming a resist pattern on said underlayer film;
a spin-on glass film forming step of forming a spin-on glass film on an exposed surface portion of said underlayer film;
a resist pattern removing step of removing said resist pattern; and
an underlayer film etching step of etching said underlayer film using said spin-on glass film as a mask.

2. The method according to claim 1, further comprising:
an ion implanting step of implanting ions in said resist pattern after said resist pattern forming step.

3. The method according to claim 1, further comprising:
an electron beam curing step of performing electron beam curing on said resist pattern after said resist pattern forming step.

4. The method according to claim 1, further comprising:
a light curing step of performing light curing on said resist pattern after said resist pattern forming step.

5. The method according to claim 1, further comprising:
a framing step of framing said resist pattern by use of an organic film after said resist pattern forming step.

6. The method according to claim 1, further comprising:
an upperlayer resist pattern forming step of forming an upperlayer resist pattern on said spin-on glass film; and
a spin-on glass film etching step of etching said spin-on glass film using said upperlayer resist pattern as a mask;
wherein said upperlayer resist pattern forming step and said spin-on glass film etching step are performed after said spin-on glass film forming step before said resist pattern removing step.

7. The method as claimed in claim 6, further comprising:
an ion implanting step of implanting ions either in said resist pattern after said resist pattern forming step, or in said upperlayer resist pattern after said upperlayer resist pattern forming step.

8. The method as claimed in claim 6, further comprising:
an electron beam curing step of performing electron beam curing either on said resist pattern after said resist pattern forming step, or on said upperlayer resist pattern after said upperlayer resist pattern forming step.

9. The method as claimed in claim 6, further comprising:
a light curing step of performing light curing either on said resist pattern after said resist pattern forming step, or on said upperlayer resist pattern after said upperlayer resist pattern forming step.

10. The method as claimed in claim 6, further comprising:
a framing step of, by use of an organic film, framing either said resist pattern after said resist pattern forming step, or said upperlayer resist pattern after said upperlayer resist pattern forming step.

11. A method for manufacturing a semiconductor device, comprising:
an underlayer film forming step of forming an underlayer film on a substrate;
a first resist pattern forming step of forming a first resist pattern on said underlayer film;
a first spin-on glass film forming step of forming a first spin-on glass film on an exposed surface portion of said underlayer film;
a planerization step of flattening a surface of said first spin-on glass film until a surface of said first resist pattern is exposed;
a second spin-on glass film forming step of forming a second spin-on glass film on said first spin-on glass film;
a second resist pattern forming step of forming a second resist pattern on said second spin-on glass film;
a spin-on glass film etching step of etching said second spin-on glass film using said second resist pattern as a mask;
a resist pattern etching step of etching said first resist pattern using said second spin-on glass film as a mask; and
an underlayer film etching step of etching said underlayer film using both said second spin-on glass film and said first spin-on glass film as masks.

12. The method as claimed in claim 11, further comprising:
an ion implanting step of implanting ions either in said first resist pattern after said first resist pattern forming step, or in said second resist pattern after said second resist pattern forming step.

13. The method as claimed in claim 11, further comprising:
an electron beam curing step of performing electron beam curing either on said first resist pattern after said first resist pattern forming step, or on said second resist pattern after said second resist pattern forming step.

14. The method as claimed in claim 11, further comprising:
a light curing step of performing light curing either on said first resist pattern after said first resist pattern forming step, or on said second resist pattern after said second resist pattern forming step.

15. The method as claimed in claim 11, further comprising:
a framing step of, by use of an organic film, framing either said first resist pattern after said first resist pattern forming step, or said second resist pattern after said second resist pattern forming step.
